(19) United States
(12) Patent Application Publication
(10) Pub. No.: US 2026/0299029 A1
(43) Pub. Date: Oct. 1, 2026

(54) METHOD AND APPARATUS FOR DIAGNOSING BATTERY PACK SAFETY OF AN ELECTRIC VEHICLE

(71) Applicants: HYUNDAI MOTOR COMPANY, Seoul (KR); KIA CORPORATION, Seoul (KR); The Industry & Academic Cooperation in Chungnam National University (IAC), Daejeon (KR)

(72) Inventors: Cheol Beom Lim, Hwaseong-si (KR); Jong Hoon Kim, Daejeon (KR)

(73) Assignees: HYUNDAI MOTOR COMPANY, Seoul (KR); KIA CORPORATION, Seoul (KR); The Industry & Academic Cooperation in Chungnam National University (IAC), Daejeon (KR)

(21) Appl. No.: 19/316,281

(22) Filed: Sep. 2, 2025

(30) Foreign Application Priority Data
Mar. 31, 2025 (KR) 10-2025-0041735

(51) Int. Cl. G01R 31/367; G01R 31/36; G01R 31/3842; G01R 31/389; H01M 10/42

(52) U.S. Cl. CPC G01R 31/367; G01R 31/3646; G01R 31/3842; G01R 31/389; H01M 10/4285

(57) ABSTRACT

A method for diagnosing safety of a battery pack includes receiving a current/voltage signal corresponding to the battery pack from a battery management system (BMS). The method further includes performing current/voltage signal processing based on the received signal. The method further includes extracting a Passive Electrochemical Impedance Spectroscopy (PEIS) pattern based on a signal processing result. The method further includes converting an image into an image for the PEIS pattern. The method further includes classifying a battery fault pattern by applying the converted image to a pre-learned model. The method further includes generating a fault tree based on the classified battery fault pattern. The method further includes monitoring safety of the battery pack based on the generated fault tree.

### CROSS-REFERENCE TO RELATED APPLICATION

This application claims the benefit of and priority to Korean Patent Application No. 10-2025-0041735, filed in the Korean Intellectual Property Office on Mar. 31, 2025, the entire contents of which are incorporated herein by reference.

### TECHNICAL FIELD

The present disclosure relates to an electric vehicle battery diagnosing technology. More particularly, the present disclosure relates to a technology for diagnosing battery pack safety.

### BACKGROUND

The safety of electric vehicle battery packs is one of the main issues for electric vehicles, which may cause serious issues for the safe operation of electric vehicles, such as fire.

Accordingly, a battery pack safety diagnosis technology is very important for ensuring electric vehicle performance and driver safety.

A conventional direct current (DC)-based battery pack safety diagnosis algorithm diagnoses safety based on mathematical models such that a battery management system (BMS) estimates the state of a battery. However, the conventional DC-based battery pack safety diagnosis algorithm does not reflect the electrochemical mechanism of an actual battery and thus does not accurately diagnose safety issues, which limits the reliability of the diagnostic results.

Each of cells within a battery pack module comprises several components such as electrodes, electrolytes, and separators, making it difficult to accurately identify the status of the battery's internal electrochemical structure by using a simple sensor. In particular, sensors that measure the voltage, current, or temperature of a battery includes a specific level of error, which causes a decrease in the accuracy of the battery pack safety diagnosis results.

To overcome the limitations of the conventional DC-based battery pack safety diagnosis algorithm, an electrochemical impedance spectroscopy (hereinafter, referred to as “EIS”) diagnosis technique is being used to diagnose safety based on the electrochemical deterioration characteristics of the battery. However, the EIS diagnosis technique not only requires separate equipment for generating and measuring EIS signals but also includes limitations in applying it to actual Electric Vehicles (EVs) due to hardware specification limitations.

The EIS for electrochemically measuring of a battery is time-consuming because it requires data collection in several frequency bands, and in situations where real-time monitoring is required, the time consumption of EIS may cause significant issues. In other words, EIS-based battery pack safety diagnosis is limited in real-time monitoring.

The subject matter described in this background section is intended to promote an understanding of the background of the disclosure and thus may include subject matter that is not already known to those of ordinary skill in the art. The statements in this section merely provide background information related to the present disclosure and may not constitute prior art.

### SUMMARY

The present disclosure provides a reliable real-time battery pack safety diagnosis technology capable of overcoming limitations of the conventional DC-based battery pack safety diagnosis method and the EIS-based battery pack safety diagnosis method, addressing the aforementioned problems occurring in the prior art while preserving advantages offered by those conventional methods.

An aspect of the present disclosure provides a method and an apparatus for diagnosing the safety of a battery pack of an electric vehicle.

An aspect of the present disclosure provides an electric vehicle battery pack safety diagnosis technology that may diagnose battery pack safety in real time by deriving a Passive Electrochemical Impedance Spectroscopy (PEIS) pattern through signal processing on BMS input voltage and current raw signals.

An aspect of the present disclosure provides an apparatus and a method for diagnosing electric vehicle battery pack safety that may classify battery pack fault patterns by performing image conversion on the PEIS pattern derived through signal processing on DC signals obtained through battery management system (BMS) such that computer learning is possible.

An aspect of the present disclosure provides electric vehicle battery pack safety diagnosis apparatus and method that may monitor battery pack safety in real-time by generating a fault tree based on battery pack fault patterns classified through computer learning.

The technical problems to be solved by the present disclosure are not limited to the aforementioned problems. Any other technical problems not mentioned herein should be clearly understood from the following description by those having ordinary skill in the art to which the present disclosure pertains.

According to an aspect of the present disclosure, a method for diagnosing safety of a battery pack includes receiving a current/voltage signal corresponding to the battery pack from a battery management system (BMS). The method further includes performing signal processing based on the received current/voltage signal. The method further includes extracting a Passive Electrochemical Impedance Spectroscopy (PEIS) pattern based on the signal processing result. The method further includes converting an image conversion into an image for the PEIS pattern. The method further includes classifying a battery fault pattern by applying the converted image to a pre-learned model. The method further includes generating a fault tree based on the classified battery fault pattern. The method further includes monitoring safety of the battery pack based on the generated fault tree.

In an embodiment, performing the signal processing may include performing a discrete wavelet transform step to remove noise from the received current/voltage signal and extract a time domain signal by decomposing frequency level-specific data. Performing the signal processing may further include a short-term Fourier transform step to split the time domain signal into segments and to convert the segments into a segment-specific frequency domain signal.

In an embodiment, in the short-term Fourier transform step, a specific overlap interval may be set between the segments.

In an embodiment, the PEIS pattern may be diagrammed based on frequency-specific AC impedance data extracted through the signal processing.

In an embodiment, converting the image into the image for the PEIS pattern may be performed on the diagrammed PEIS pattern so as to be in a form of a straight line through a Bresenham algorithm.

In an embodiment, the pre-learned model may be a convolutional neural network model.

In an embodiment, the fault tree may be designed to logically structure all routes of predetermined level-specific events capable of occurring to correspond to the battery pack. Safety diagnosis may be performed on the battery pack based on a monitored result indicating that a change in the PEIS pattern occurs.

In an embodiment, the predetermined level-specific events may include a basic event including a high temperature, overcharging, and a high current; a middle event including a cathode issue; and a top event including thermal runaway.

In an embodiment, the method may further include outputting a predetermined warning alarm message including a safety diagnosis result of the battery pack.

In an embodiment, the predetermined warning alarm message may include a first identifier for identifying a diagnosis event and a second identifier for identifying a level corresponding to the first identifier.

According to an aspect of the present disclosure, a computing device for diagnosing safety of a battery pack includes a memory configured to store instructions and a processor. The processor is configured, by executing the instructions, to receive a current/voltage signal corresponding to the battery pack from a BMS. The processor is further configured to perform current/voltage signal processing based on the received signal. The processor is further configured to extract a PEIS pattern based on a signal processing result. The processor is further configured to convert into an image for the PEIS pattern. The processor is further configured to classify a battery fault pattern by applying the converted image to a pre-learned model. The processor is further configured to generate a fault tree based on the classified battery fault pattern. The processor is further configured to monitor safety of the battery pack based on the generated fault tree.

In an embodiment, the processor is configured to perform the signal processing by performing discrete wavelet transform to remove noise from the received current/voltage signal and to extract a time domain signal by decomposing frequency level-specific data. The processor is configured to perform the signal processing by performing short-term Fourier transform to split the time domain signal into segments and to convert the segments into a segment-specific frequency domain signal.

In an embodiment, the processor may be further configured to perform the short-term Fourier transform by setting a specific overlap interval between the segments.

In an embodiment, the processor may be further configured to diagram the PEIS pattern based on frequency-specific AC impedance data extracted through the signal processing.

In an embodiment, the processor may be configured to perform the image conversion on the diagrammed PEIS pattern so as to be in a form of a straight line through a Bresenham algorithm.

In an embodiment, the pre-learned model may be a convolutional neural network model.

In an embodiment, the processor may be further configured to design the fault tree by logically structuring all routes of predetermined level-specific events capable of occurring to correspond to the battery pack. The processor may be further configured to perform safety diagnosis on the battery pack based on a monitored result indicating that a change in the PEIS pattern occurs.

In an embodiment, the predetermined level-specific events may include a basic event including a high temperature, overcharging, and a high current; a middle event including a cathode issue; and a top event including thermal runaway.

In an embodiment, the processor may be further configured to generate and output a predetermined warning alarm message including a safety diagnosis result of the battery pack.

In an embodiment, the predetermined warning alarm message may include a first identifier for identifying a diagnosis event and a second identifier for identifying a level corresponding to the first identifier.

### BRIEF DESCRIPTION OF THE DRAWINGS

The above and other objects, features, and advantages of the present disclosure should be more apparent from the following detailed description taken in conjunction with the accompanying drawings:

FIG. 1 is a block diagram illustrating a configuration of an electric vehicle battery diagnosing system, according to an embodiment of the present disclosure;

FIG. 2 is a flowchart illustrating an overall battery pack safety diagnosis procedure, according to an embodiment of the present disclosure;

FIG. 3 is a block diagram illustrating a detailed configuration of a battery pack safety diagnosis device, according to an embodiment of the present disclosure;

FIG. 4 is a flowchart for describing a procedure of converting a Passive Electrochemical Impedance Spectroscopy (PEIS) pattern image and classifying a pre-learning model-based battery fault in a battery pack safety diagnosis device, according to an embodiment of the present disclosure;

FIG. 5 is a flowchart illustrating a procedure for designing a fault tree based on a classified PEIS pattern (a battery fault pattern) in a battery pack safety diagnosis device, according to an embodiment of the present disclosure;

FIG. 6 is a flowchart for describing a method of a battery pack safety diagnosis device, according to an embodiment of the present disclosure;

FIG. 7 illustrates a computing device, according to an embodiment of the present disclosure;

FIG. 8 is a diagram for describing discrete wavelet transform, which is a signal processing technique, according to an embodiment of the present disclosure;

FIG. 9 is a diagram for describing a short-term discrete Fourier transform, which is another signal processing technique, according to an embodiment of the present disclosure;

FIG. 10 is a diagram for describing a structure and a function of a CNN algorithm, according to an embodiment of the present disclosure; and

FIG. 11 is a diagram for describing a Bresenham algorithm for image conversion of a PEIS pattern, according to an embodiment of the present disclosure.

### DETAILED DESCRIPTION

Hereinafter, some embodiments of the present disclosure are described in detail with reference to the accompanying drawings. In adding reference numerals to components of each drawing, it should be noted that the same components include the same reference numerals, although they are indicated on another drawing. In describing embodiments of the present disclosure, detailed descriptions associated with well-known functions or configurations have been omitted when they may make subject matters of the present disclosure unnecessarily obscure.

In describing components of embodiments of the present disclosure, the terms first, second, A, B, (a), (b), and the like may be used herein. These terms are only used to distinguish one element from another element, but do not limit the corresponding elements irrespective of the nature, order, or priority of the corresponding elements. Furthermore, unless otherwise defined, all terms used herein, including technical or scientific terms, include the same meaning as commonly understood by one of ordinary skill in the art to which the present disclosure belongs. It should be understood that terms used herein should be interpreted as including a meaning that is consistent with their meaning in the context of the present disclosure and the relevant art and should not be interpreted in an idealized or overly formal sense unless expressly so defined herein. When a controller, module, component, device, element, or the like of the present disclosure is described as having a purpose or performing an operation, function, or the like, the controller, module, component, device, element, or the like should be considered herein as being “configured to” meet that purpose or to perform that operation or function. Each controller, module, component, device, element, and the like may separately embody or be included with a processor and a memory, such as a non-transitory computer readable media, as part of the apparatus.

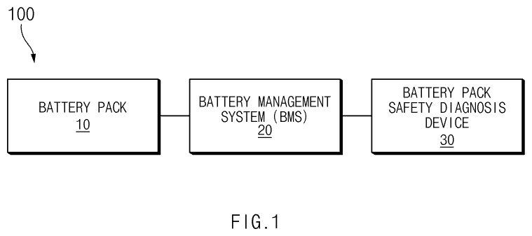

Hereinafter, embodiments of the present disclosure are described in detail with reference to FIGS. 1-11.

FIG. 1 is a block diagram illustrating a configuration of an electric vehicle battery diagnosing system, according to an embodiment of the present disclosure.

Referring to FIG. 1, an electric vehicle battery diagnosis system 100 may comprise a battery pack 10, a battery management system (hereinafter, referred to as a ‘BMS’) 20, and a battery pack safety diagnosis device 30.

The battery pack 10 is in the final form of a battery mounted on an electric vehicle. The pack is a bundle of several modules, and each module may include several battery cells.

The module is a battery assembly in which the specific number of battery cells are bundled together and placed in a frame to protect the battery cells from external shock, heat, vibration, or the like.

The battery cell may be the basic unit of a battery capable of using electrical energy for charging/discharging and may be implemented by placing anode/cathode/separator/electrolyte in an aluminum case.

The BMS 20 may manage a temperature, a voltage, a current, or the like of the battery module.

The BMS 20 according to an embodiment may be mounted inside the battery pack 10, and various control and protection systems, such as a cooling device, may be provided inside the battery pack 10.

The BMS 20 according to an embodiment may detect a voltage difference between battery cells and may also perform cell balancing when a voltage imbalance between cells is detected.

In general, when battery stability is not secured, the risk of fire may increase. Accordingly, accurate safety diagnosis of the battery pack is important not only to ensure the performance and durability of a battery but also to ensure a driver's safety.

The BMS 20 may monitor the voltage and current of individual cells in the battery pack 10 while a vehicle is driving, may generate voltage and current signals, and may transmit the voltage and current signals to the battery pack safety diagnosis device 30.

The battery pack safety diagnosis device 30 may derive passive electrochemical impedance spectroscopy (hereinafter, referred to as “PEIS”) data for each battery cell by performing signal processing on the voltage and current signals received from the BMS 20. Here, the voltage and current signals received from the BMS 20 are DC signals, and the signal processing may include Discrete Wavelet Transform (hereinafter, referred to as “DWT”) or Short Term Fourier Transform (hereinafter, referred to as “STFT”).

The PEIS according to an embodiment of the present disclosure may extract cell-level EIS data by processing the voltage/current raw signals from the BMS 20 of a vehicle without a separate EIS device.

The DWT is a transform for decomposing a given signal into several sets, and each set is a time series of coefficients for describing time changes in a signal in the corresponding frequency band. The DWT is a mathematical process of quantifying how much energy is included within a specific frequency band at a specific time within a signal.

The actual voltage and current raw signals input from the BMS 20 includes noise components (in particular, noise components in a high-frequency domain) based on operating environments and sensor characteristics (or performance), and these noise components need to be removed to extract reliable AC impedance data.

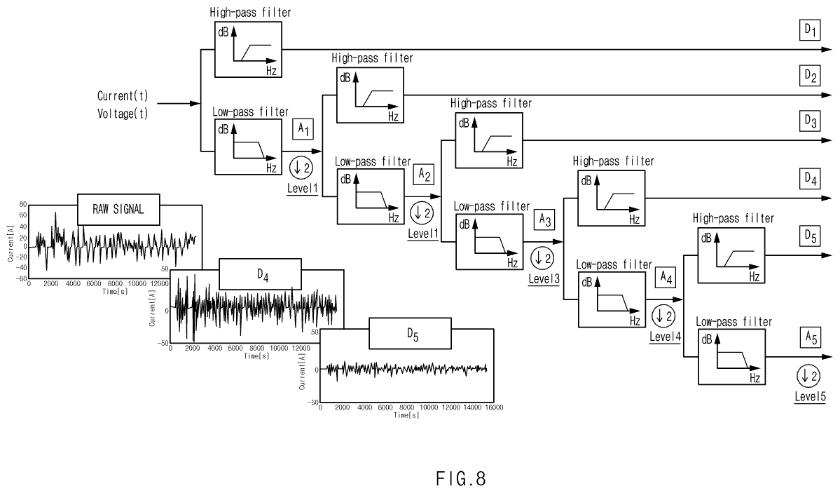

Accordingly, as illustrated in FIG. 8, the DWT may be implemented to extract time domain signals by decomposing frequency level-specific signals by applying band filters for removing noise included in the voltage and current raw signals received from the BMS 20 and by applying multi-resolution analysis (MRA) techniques for decomposing input signals into high-frequency signals and low-frequency signals.

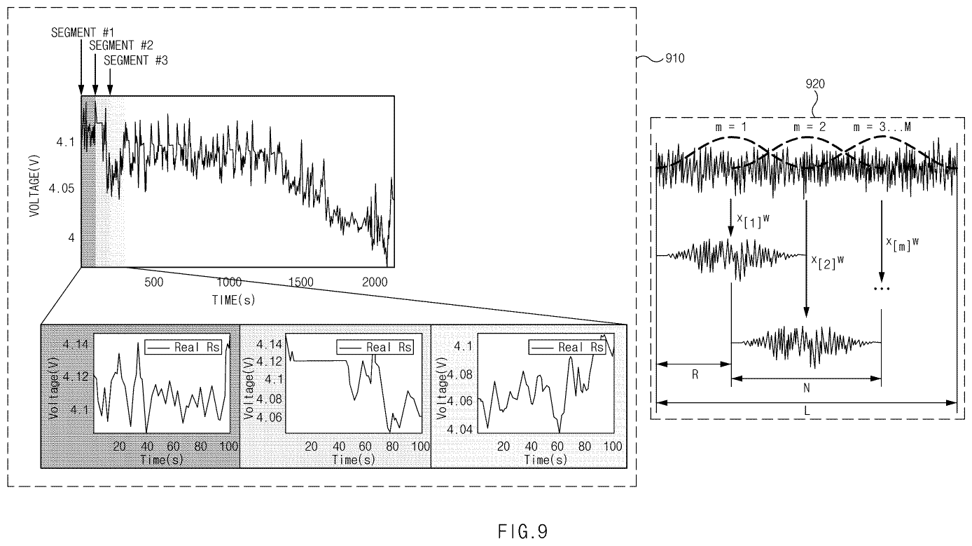

The STFT may be one of Fourier transforms of converting a time domain signal into a frequency domain signal and may be used to determine the sinusoidal frequency and phase components of a local section of a signal when the signal is changed as time goes by. In particular, as shown in FIG. 9, the STFT may be implemented as logic that divides a long time domain raw signal into short segments of the same length, performs a Fourier transform on each short segment individually, and applies Ohm's law of voltage/current in the transformed frequency domain to extract frequency-specific AC impedance.

In the case of the raw voltage and current signals input from the BMS 20 when an electric vehicle is driving, it is difficult to extract frequency-specific periodicity of a long time interval in real time. The battery pack safety diagnosis device 30 according to an embodiment of the present disclosure may derive real-time voltage and current frequency characteristics by splitting a raw signal into segments of a short time unit through application of the STFT and then performing a Fourier transform on each segment. In an embodiment, as shown in reference numeral 910 according to an embodiment of the present disclosure, segmentation is applied to a raw signal. As shown in reference numeral 920, when an overlap interval between segments is set, frequency-specific AC impedance data may be extracted quickly (e.g., in units of one second), thereby diagnosing real-time safety of a battery pack.

The battery pack safety diagnosis device 30 may extract PEIS data for individual cells within a module through the above-described signal processing and may derive a PEIS pattern image by diagramming the extracted PEIS data. Here, the PEIS pattern may be derived for each SOC environment.

The battery pack safety diagnosis device 30 may perform image conversion on the diagrammed PEIS pattern.

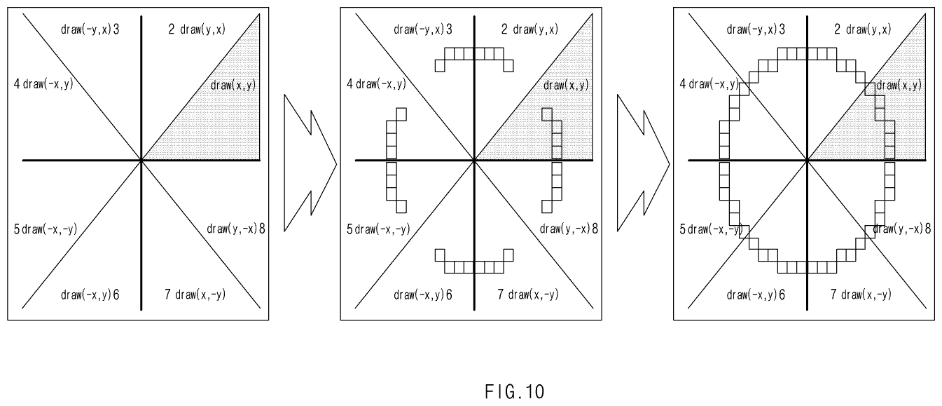

In an embodiment, a Bresenham algorithm may be applied to the image conversion on the PEIS pattern. The Bresenham algorithm refers to an algorithm created in computer graphics to draw a straight line by using only integer calculations, excluding real number calculations, which are complex and slow. In detail, the Bresenham algorithm refers to a method of efficiently drawing a straight line by using integer coordinates on a pixel-based screen (pixel). As shown in FIG. 10, the Bresenham algorithm may determine coordinates of each pixel, where a straight line is drawn, based on coordinate information of start and end points, and may track an error value by selecting x coordinate or y coordinate according to the slope of the straight line. In this case, when the error value exceeds a specific reference, the Bresenham algorithm may approximately generate a straight line by adjusting x coordinate or y coordinate and selecting pixels one by one through generating the straight line and integer operations.

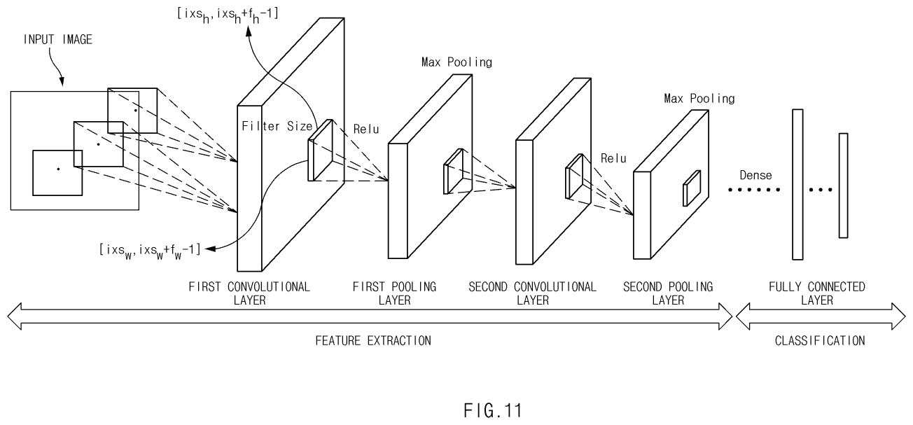

The battery pack safety diagnosis device 30 may classify battery fault patterns by inputting the converted image of the PEIS pattern into a pre-learned model to extract image features. In an embodiment, a convolutional neural network (CNN) model illustrated in FIG. 11 may be applied to a learning model for battery fault pattern classification, but is not limited thereto, and various artificial intelligence (or machine learning) learning models capable of automatically extracting image features and efficiently classifying patterns may be applied.

The CNN may automatically extract features included in the converted image, and may efficiently analyze complex nonlinear patterns through layer-specific learning. The PEIS data refers to time series data and includes nonlinear characteristics. Accordingly, the CNN may be suitable for visualizing and analyzing these nonlinear structures. Referring to FIG. 11, the CNN may pre-assign a name (label) to the corresponding image when inputting the converted image and then may extract features included in the input image by using a convolution layer and a pooling layer. Next, patterns may be classified by applying the extracted features to the fully connected layer to perform label learning on the input image. The battery pack safety diagnosis device 30 may classify battery fault patterns by comparing image features based on a pre-learned model when a new conversion image is input.

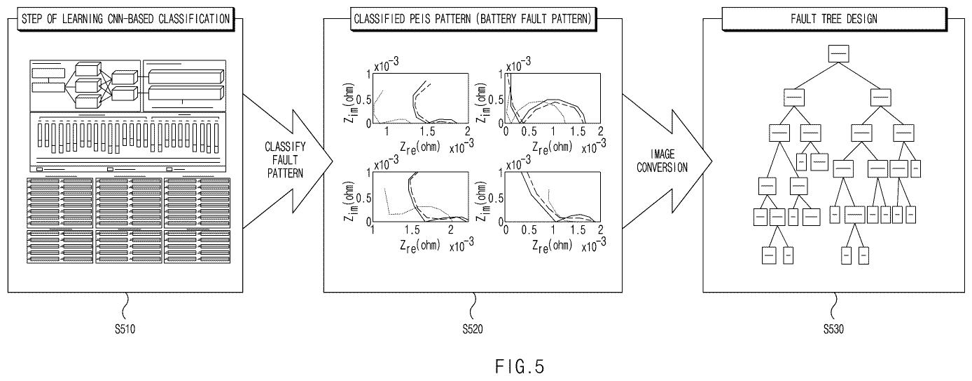

The battery pack safety diagnosis device 30 may generate a fault tree based on the classified battery fault pattern, and may perform battery pack safety monitoring by using the generated fault tree. A method of generating a fault tree and monitoring safety is described in detail with reference to FIG. 5 below.

The battery pack safety diagnosis device 30 according to an embodiment may be mounted inside the battery pack 10. According to another embodiment, the battery pack safety diagnosis device 30 may be implemented as an integrated device with the BMS 20.

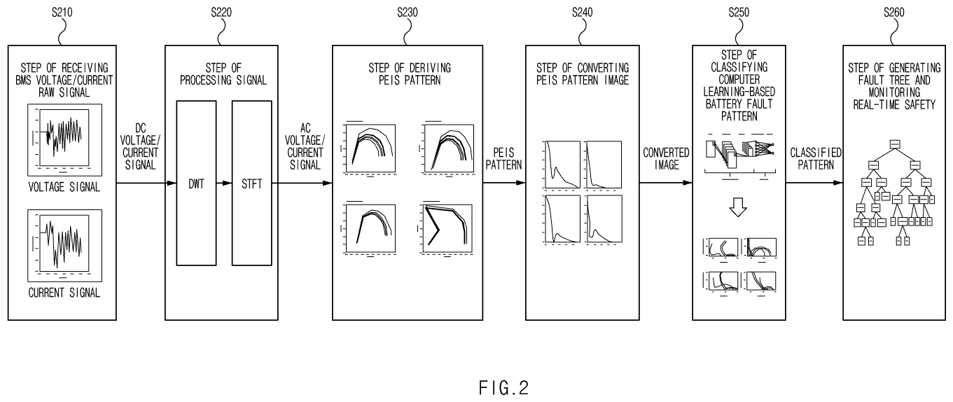

FIG. 2 is a flowchart illustrating an overall battery pack safety diagnosis procedure, according to an embodiment of the present disclosure.

Referring to FIG. 2, the battery pack safety diagnosis procedure may include S210 of receiving a BMS voltage/current raw signal, S220 of processing a signal, S230 of deriving a PEIS pattern, S240 of converting a PEIS pattern image, S250 of classifying a computer learning-based battery fault pattern, and S260 of generating a fault tree and monitoring real-time safety.

In S210 of receiving a BMS voltage/current raw signal, the battery pack safety diagnosis device 30 may receive voltage and current raw signals from the BMS 20. Here, the voltage and current raw signals may be DC signals.

In S220 of processing a signal, the battery pack safety diagnosis device 30 may remove a noise component included in the received raw signal and then may perform DWT (i.e., Discrete Wavelet Transform) for extracting a time domain signal by decomposing frequency level-specific data.

Moreover, in S220 of processing a signal, the battery pack safety diagnosis device 30 may perform STFT (i.e., Short Term Fourier Transform) for extracting frequency-specific AC impedance data based on DC voltage and current signal data of individual cells in the battery pack 10 by converting a time domain signal into a frequency domain signal.

In S230 of deriving a PEIS pattern, the battery pack safety diagnosis device 30 may derive a PEIS pattern based on AC impedance data.

In S240 of converting a PEIS pattern image, the battery pack safety diagnosis device 30 may perform image conversion of the PEIS pattern.

In S250 of classifying a computer learning-based battery fault pattern, the battery pack safety diagnosis device 30 may classify a battery fault pattern by applying the converted image to a pre-learned model. For example, CNN may be applied as a learning model used for fault pattern classification.

In S260 of generating a fault tree and monitoring real-time safety, the battery pack safety diagnosis device 30 may perform real-time battery pack safety diagnosis by generating a fault tree based on the classified battery fault pattern.

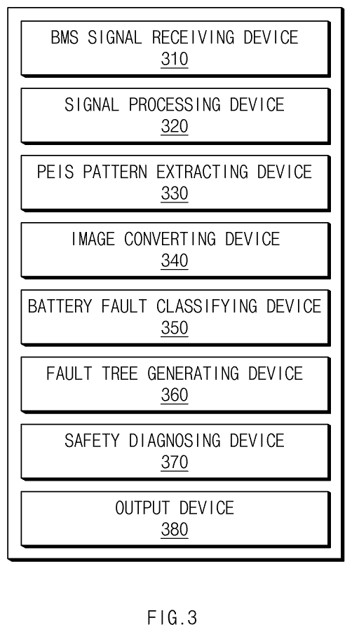

FIG. 3 is a block diagram illustrating a detailed configuration of a battery pack safety diagnosis device, according to an embodiment of the present disclosure.

Referring to FIG. 3, the battery pack safety diagnosis device 30 may be configured to include at least one of a BMS signal receiving device 310, a signal processing device 320, a PEIS pattern extracting device 330, an image converting device 340, a battery fault classifying device 350, a fault tree generating device 360, a safety diagnosing device 370, or an output device 380.

The BMS signal receiving device 310 may receive voltage and current raw signals from the BMS 20. Here, the voltage and current raw signals may be DC signals.

The signal processing device 320 may remove noise components included in the received raw signals and then may perform DWT for extracting time domain signals by decomposing frequency level-specific data and may perform STFT for extracting frequency-specific AC impedance data based on DC voltage and current signals of individual cells in the battery pack 10 by converting time domain signals into frequency domain signals.

The PEIS pattern extracting device 330 may extract real-time PEIS patterns based on the AC impedance data.

The image converting device 340 may perform image conversion on the extracted PEIS pattern. In an embodiment, the image converting device 340 may perform PEIS pattern image conversion by applying a Bresenham algorithm.

The battery fault classifying device 350 may classify electric vehicle battery operating environments (i.e., battery fault patterns (or battery fault types)) by applying the converted image to a pre-learned model. In an embodiment, the battery fault classifying device 350 may classify the battery fault patterns corresponding to the converted image by using a convolutional neural network.

The fault tree generating device 360 may generate (or design) a fault tree, as shown in FIG. 5, by performing fault tree analysis (FTA) based on the classified battery fault patterns.

The FTA algorithm may be implemented to design a system by defining a top event (e.g., thermal runaway) and logically structuring all possible routes where the corresponding event occurs.

For example, according to the FTA algorithm, a fault tree generating device may create a fault tree by defining high temperature, overcharging, and high current as basic events, by defining cathode issues as middle events, and by defining thermal runaway as top events.

The safety diagnosing device 370 may perform real-time safety monitoring of the battery pack 10 based on the fault tree designed when a change in the PEIS pattern occurs. For example, the safety diagnosing device 370 may perform safety diagnosis by comparing routes corresponding to predefined basic events, middle events, and top events when a change in the PEIS pattern occurs.

For example, when charge transfer resistance R_{ct} increases and a phase is 0, the safety diagnosing device 370 may diagnose that a high temperature event occurs. For another example, when the charge transfer resistance R_{ct} increases and double layer capacitance C_{dl} increases, the safety diagnosing device 370 may diagnose that a low temperature event or plating occurs.

When a result of the battery pack safety diagnosis indicates that a specific event is detected, the output device 380 may generate a warning alarm message corresponding to the corresponding event and may transmit the warning alarm message to an output device (e.g., a cluster) equipped in a vehicle.

In an embodiment, the warning alarm message may include a first identifier for identifying a diagnosis event and a second identifier for identifying a level corresponding to the first identifier.

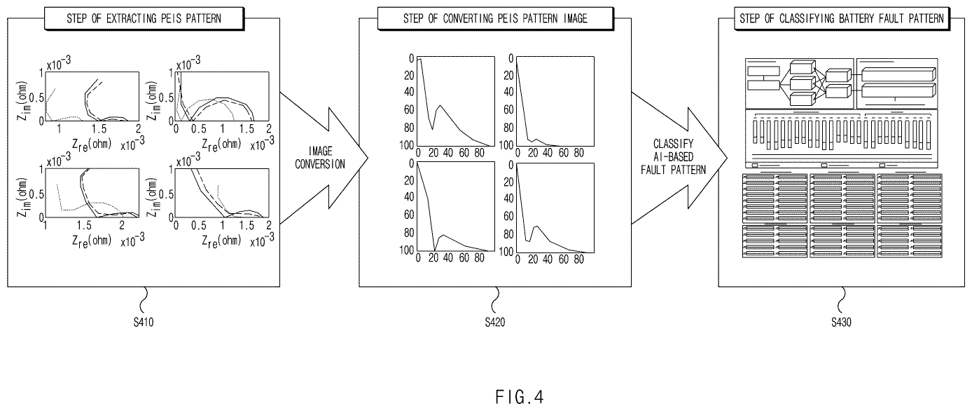

FIG. 4 is a diagram for describing a procedure of converting a PEIS pattern image and classifying a pre-learning model-based battery fault in a battery pack safety diagnosis device, according to an embodiment of the present disclosure.

Referring to FIG. 4, the battery pack safety diagnosis device 30 may extract and diagram a PEIS pattern based on AC impedance data extracted through signal processing of a voltage/current signal received from the BMS 20 (S410).

The battery pack safety diagnosis device 30 may perform image conversion on the PEIS pattern (S420).

The battery pack safety diagnosis device 30 may classify a battery fault pattern by applying the converted image to a pre-learned model (S430).

FIG. 5 is a flowchart illustrating a procedure for designing a fault tree based on a classified PEIS pattern (a battery fault pattern) in a battery pack safety diagnosis device, according to an embodiment of the present disclosure.

As illustrated in reference numeral S510 of FIG. 5, the battery pack safety diagnosis device 30 may perform CNN-based classification learning (S510).

The battery pack safety diagnosis device 30 may obtain information about battery fault patterns through classification learning (S520).

The battery pack safety diagnosis device 30 may design a fault tree by applying an FTA algorithm based on a classified battery fault patterns (S530).

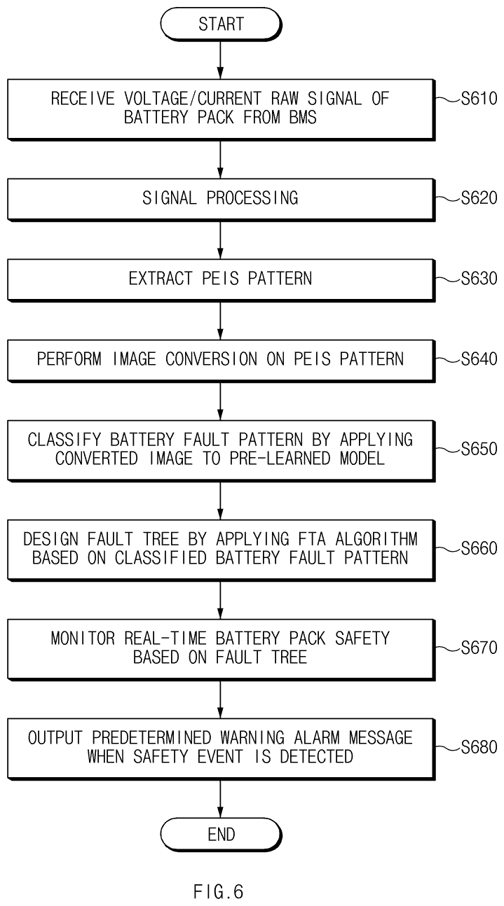

FIG. 6 is a flowchart for describing a method of a battery pack safety diagnosis device, according to an embodiment of the present disclosure.

Referring to FIG. 6, the battery pack safety diagnosis device 30 may receive a voltage/current signal of the battery pack 10 from the BMS 20 (S610).

The battery pack safety diagnosis device 30 may perform signal processing on the received voltage/current signal (S620). Here, the signal processing may include the DWT and STFT described above.

The battery pack safety diagnosis device 30 may extract a PEIS pattern based on AC impedance data obtained through the signal processing (S630).

The battery pack safety diagnosis device 30 may perform image conversion on the extracted PEIS pattern (S640). The image conversion according to an embodiment may be performed by applying a Bresenham algorithm.

The battery pack safety diagnosis device 30 may classify a battery fault pattern by applying the converted image to a pre-learned model (S650). Here, a convolutional neural network may be applied as a learning model for the converted image.

The battery pack safety diagnosis device 30 may design a fault tree by performing an FTA algorithm based on the classified battery fault pattern (S660).

The battery pack safety diagnosis device 30 may perform real-time battery pack safety monitoring based on the designed fault tree (S670).

The battery pack safety diagnosis device 30 may output a warning alarm message including the battery pack safety diagnosis result when the monitoring result indicates that a predetermined safety event is detected (S680).

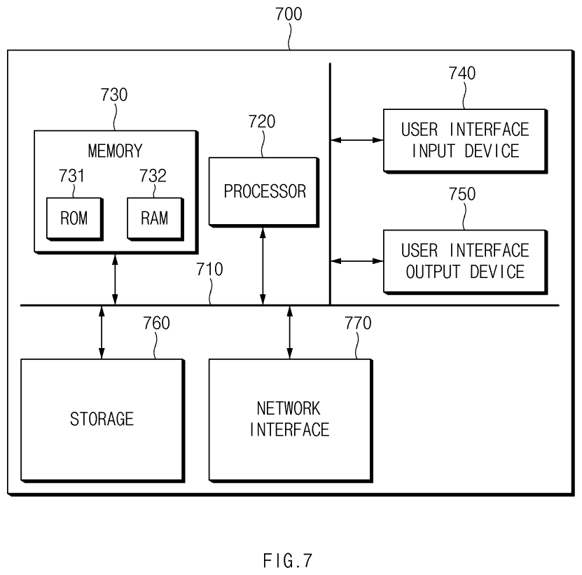

FIG. 7 illustrates a computing device, according to an embodiment of the present disclosure.

Referring to FIG. 7, a computing device 700 may include at least one of at least one processor 720, a memory 730, a user interface input device 740, a user interface output device 750, a storage 760, or a network interface 770, which is connected via a bus 710.

The network interface 770 according to an embodiment may perform at least one of diagnostic communication, intra-vehicle communication, or communication with a server outside a vehicle. The network interface 770 may operate in conjunction with the BMS 20, a navigation system (e.g., an AVN (Audio, Video and Navigation) system), or a cluster through the in-vehicle communication. The in-vehicle communication according to an embodiment may include, but is not limited to, at least one of Controller Area Network (CAN) communication, Local Interconnect Network (LIN) communication, FlexRay communication, MOST (Media Oriented Systems. Transport) communication, or Ethernet communication.

The processor 720 may be a central processing unit (CPU) or a semiconductor device that processes instructions stored in the memory 730 and/or the storage 760. Each of the memory 730 and the storage 760 may include various types of volatile or nonvolatile storage media. For example, the memory 730 may include a read only memory (ROM) 731 and a random access memory (RAM) 732.

Thus, the operations of the methods or algorithms described in connection with the embodiments disclosed in the present disclosure may be directly implemented with a hardware module, a software module, or a combination of the hardware module and the software module, which is executed by the processor 720. The software module may reside on a storage medium (i.e., the memory 730 and/or the storage 760) such as a RAM, a flash memory, a ROM, an erasable and programmable ROM (EPROM), an electrically EPROM (EEPROM), a register, a hard disc, a removable disc, or a compact disc-ROM (CD-ROM).

The storage medium may be coupled to the processor 720. The processor 720 may read out information from the storage medium and may write information in the storage medium. Alternatively, the storage medium may be integrated with the processor 720. The processor 720 and storage medium may be implemented with an application specific integrated circuit (ASIC). The ASIC may be provided within a controller in the vehicle. Alternatively, the processor 720 and the storage medium may reside as separate components within an electric vehicle.

In an embodiment, the computing device 700 may be implemented to perform the above-described at least one function and the above-described at least one method disclosed in FIGS. 1-6 and 8-11 described above and may be applied to at least one of the above-described components of the electric vehicle battery diagnosis system 100.

The above description is merely an example of the technical idea of the present disclosure, and various modifications and variations may be made by one having ordinary skill in the art without departing from the essential characteristic of the present disclosure.

Accordingly, embodiments of the present disclosure are intended not to limit but to explain the technical idea of the present disclosure, and the scope and spirit of the present disclosure is not limited by the above embodiments. The scope of protection of the present disclosure should be construed by the attached claims, and all equivalents thereof should be construed as being included within the scope of the present disclosure.

The present technology provides a method and an apparatus for diagnosing the safety of a battery pack of an electric vehicle.

Furthermore, the present technology provides an electric vehicle battery pack safety diagnosis technology that may diagnose battery pack safety in real time by deriving a PEIS pattern through signal processing on BMS input voltage and current raw signals.

Also, the present technology provides an apparatus and a method for diagnosing electric vehicle battery pack safety that may classify battery pack fault patterns by performing image conversion on the PEIS pattern derived through signal processing on DC signals obtained through BMS such that computer learning is possible.

An aspect of the present disclosure provides electric vehicle battery pack safety diagnosis apparatus and method that may monitor battery pack safety in real-time by generating a fault tree based on battery pack fault patterns classified through computer learning.

Moreover, the present technology may provide a cost-effective and reliable real-time battery pack safety diagnosis technology based on PEIS patterns, compared to a conventional DC-based battery pack safety diagnosis method and an EIS-based battery pack safety diagnosis method.

In addition, the present technology may not only monitor real-time battery safety through a fault tree generated based on the PEIS pattern classification results but also provide a battery pack safety diagnosis technology capable of preventing safety issues in advance by classifying operating environments of a battery.

Furthermore, the present technology may monitor internal states of the battery in real time and may detect potential issues early, thereby ensuring the safety of drivers of electric vehicles and preventing fatal accidents such as fires.

Besides, a variety of effects directly or indirectly understood through the present disclosure may be provided.

Hereinabove, although the present disclosure is described with reference to embodiments and the accompanying drawings, the present disclosure is not limited thereto. The present disclosure may be variously modified and altered by those having ordinary skill in the art to which the present disclosure pertains without departing from the spirit and scope of the present disclosure claimed in the following claims.

What is claimed is:

1. A method for diagnosing safety of a battery pack, the method comprising:
receiving a current/voltage signal corresponding to the battery pack from a battery management system (BMS);
performing signal processing based on the received current/voltage signal;
extracting a Passive Electrochemical Impedance Spectroscopy (PEIS) pattern based on a signal processing result;
converting an image into an image for the PEIS pattern;
classifying a battery fault pattern by applying the converted image to a pre-learned model;
generating a fault tree based on the classified battery fault pattern; and
monitoring safety of the battery pack based on the generated fault tree.

2. The method of claim 1, wherein performing the signal processing includes:
performing a discrete wavelet transform step to remove noise from the received current/voltage signal and to extract a time domain signal by decomposing frequency level-specific data; and
performing a short-term Fourier transform step to split the time domain signal into segments and to convert the segments into a segment-specific frequency domain signal.

3. The method of claim 2, wherein in the short-term Fourier transform step, a specific overlap interval is set between the segments.

4. The method of claim 1, wherein the PEIS pattern is diagrammed based on frequency-specific AC impedance data extracted through the signal processing.

5. The method of claim 4, wherein converting the image into the image for the PEIS pattern is performed on the diagrammed PEIS pattern so as to be in a form of a straight line through a Bresenham algorithm.

6. The method of claim 1, wherein the pre-learned model is a convolutional neural network model.

7. The method of claim 1, wherein the fault tree is designed to logically structure all routes of predetermined level-specific events capable of occurring to correspond to the battery pack, and
wherein safety diagnosis is performed on the battery pack based on a monitored result indicating that a change in the PEIS pattern occurs.

8. The method of claim 7, wherein the predetermined level-specific events include:
a basic event including a high temperature, overcharging, and a high current;
a middle event including a cathode issue; and
a top event including thermal runaway.

9. The method of claim 7, further comprising:
outputting a predetermined warning alarm message including a safety diagnosis result of the battery pack.

10. The method of claim 9, wherein the predetermined warning alarm message includes a first identifier for identifying a diagnosis event and a second identifier for identifying a level corresponding to the first identifier.

11. A computing device for diagnosing safety of a battery pack, the computing device comprising:
a memory configured to store instructions; and
a processor configured, by executing the instructions, to:
receive a current/voltage signal corresponding to the battery pack from a BMS;
perform signal processing based on the received current/voltage signal;
extract a PEIS pattern based on a signal processing result;
covert an image into an image for the PEIS pattern;
classify a battery fault pattern by applying the converted image to a pre-learned model;
generate a fault tree based on the classified battery fault pattern; and
monitor safety of the battery pack based on the generated fault tree.

12. The computing device of claim 11, wherein the processor is configured to perform the signal processing by:
performing discrete wavelet transform to remove noise from the received current/voltage signal and to extract a time domain signal by decomposing frequency level-specific data; and
performing short-term Fourier transform to split the time domain signal into segments and to convert the segments into a segment-specific frequency domain signal.

13. The computing device of claim 12, wherein the processor is further configured to:
perform the short-term Fourier transform by setting a specific overlap interval between the segments.

14. The computing device of claim 11, wherein the processor is further configured to:
diagram the PEIS pattern based on frequency-specific AC impedance data extracted through the signal processing.

15. The computing device of claim 14, wherein the processor is further configured to:
perform the image conversion on the diagrammed PEIS pattern so as to be in a form of a straight line through a Bresenham algorithm.

16. The computing device of claim 11, wherein the pre-learned model is a convolutional neural network model.

17. The computing device of claim 11, wherein the processor is further configured to:
design the fault tree by logically structuring all routes of predetermined level-specific events capable of occurring to correspond to the battery pack; and
perform safety diagnosis on the battery pack based on a monitored result indicating that a change in the PEIS pattern occurs.

18. The computing device of claim 17, wherein the predetermined level-specific events include:
a basic event including a high temperature, overcharging, and a high current;
a middle event including a cathode issue; and
a top event including thermal runaway.

19. The computing device of claim 17, wherein the processor is further configured to:
generate and output a predetermined warning alarm message including a safety diagnosis result of the battery pack.

20. The computing device of claim 19, wherein the predetermined warning alarm message includes a first identifier for identifying a diagnosis event and a second identifier for identifying a level corresponding to the first identifier.
